(19) United States
(12) Patent Application Publication
(10) Pub. No.: US 2010/0139962 A1
(43) Pub. Date: Jun. 10, 2010

(54) WIRING BOARD AND METHOD OF MANUFACTURING THE SAME

(75) Inventor: Kentaro KANEKO, Nagano (JP)

Correspondence Address: KRATZ, QUINTOS & HANSON, LLP, 1420 K Street, N.W., 4th Floor, WASHINGTON, DC, 20005, US

(73) Assignee: SHINKO ELECTRIC INDUSTRIES CO., LTD., Nagano-shi (JP)

(21) Appl. No.: 12/628,284

(22) Filed: Dec. 1, 2009

(30) Foreign Application Priority Data
Dec. 10, 2008 (JP) 2008-314434

(51) Int. Cl. H05K 1/16; H05K 3/00

(52) U.S. Cl. 174/260; 427/97.3

(57) ABSTRACT

A wiring board includes a structure in which a plurality of wiring layers are stacked one on top of another with an insulating layer (resin layer) interposed therebetween, and the wiring layers are connected to each other through a via formed in each of the resin layers. A recessed portion is formed in an annular shape surrounding a chip mounting area on the outermost resin layer on a chip mounting surface side of the wiring board. Alternatively, a projected portion is formed instead of the recessed portion.

### CROSS-REFERENCE TO RELATED APPLICATIONS

This application is based on and claims priority of Japanese Patent Application No. 2008-314434 filed on Dec. 10, 2008, the entire contents of which are incorporated herein by reference.

### BACKGROUND OF THE INVENTION

(a) Field of the Invention

The present invention relates to a wiring board for use in flip chip mounting of an electronic component such as a semiconductor element (chip), and to a method of manufacturing the same. The aforementioned wiring board is hereinafter also referred to as a “semiconductor package” for the sake of convenience.

(b) Description of the Related Art

In a structure in which a semiconductor chip is flip-chip bonded onto a wiring board, it is a general practice to reinforce the connection between the chip and the board by filling a gap therebetween with underfill resin in order to secure the reliability of the connection between the chip and the board. To bring about the reinforcement effect, filling is performed so that the underfill resin can slightly overflow from the gap between the chip and the board onto the periphery thereof, and form the skirt of a mountain, which spreads downwardly from the chip when viewed in cross section. Specifically, resin needs to be filled in such a manner that the resin overflowed from the gap between the chip and the board further flows upwardly along a sidewall portion of the chip, and forms a fillet portion.

Depending on the viscosity of the underfill resin used to fill the gap between the chip and the board, the underfill resin after the filling has a high fluidity (when viscosity is high) or a low fluidity (when viscosity is low). The change in the fluidity influences the flowing manner (behavior) of the resin within the area between the chip and the board, and the range in which the resin overflowing from the gap between the chip and the board spreads onto the periphery thereof.

The underfill resin is infiltrated into a small gap (approximately 50 μm in the state of the art) between the chip and the board by capillary action. Here, the resin with a low fluidity flows only to a small extent. Thus, in the resin in the inside of an opening portion between the chip and the board, a void (air bubble) is highly likely to be formed during a process in which the resin flows to the inside of the opening portion from a peripheral portion (injection portion) of the opening portion along the outer periphery of the chip. When a void is formed, the reliability of the connection between the chip and the wiring board decreases because a sufficient bonding strength cannot be obtained. In addition, there is a concern that a crack is produced in the resin because the air in the void expands due to a heating (curing) process after the resin filling.

In order to avoid the generation of such a void, underfill resin having a low viscosity may be used. However, the resin with a high fluidity flows to a large extent, so that an “outflow” range of the resin overflowing from the gap between the chip and the board may spread more than necessary. In this case, a wiring, a circuit element and the like disposed around the chip are adversely influenced. In particular, such an adverse influence is more notable on wiring boards which are generally used for high-density packaging. With this regard, various techniques have been proposed for restricting the outflow range of the resin overflowing from the gap between the chip and the board.

An example of the technique is described in Japanese unexamined Patent Publication (JPP) (Kokai) 2006-351559. This publication discloses a wiring board provided with a protection resist layer which covers a wiring pattern so as to surround a chip mounting area on a resin board. In this wiring board, a frame-shaped resin dam is formed on the protection resist layer. Then, underfill resin is filled into a gap between a semiconductor chip mounted within the chip mounting area and the resin board. The underfill resin overflowing onto the protection resist layer from the gap between the chip and the board is blocked by the frame-shaped resin dam.

In addition, JPP (Kokai) 2007-59596 describes another related technique. This publication discloses a semiconductor device in which a semiconductor chip is flip-chip bonded onto a surface of a wiring board. In this wiring board, a frame-shaped dam for restricting the outflow range of underfill resin is provided on the board surface in a way to surround the entire circumference of the semiconductor chip. Moreover, solder balls (external connection terminals) for a semiconductor chip are arranged outside the frame-shaped dam, and the board surface except for the flip-chip bonded position and the positions where the solder balls are arranged is covered by a solder resist layer. Furthermore, a trench is provided in the solder resist layer in the area between a corner portion of the semiconductor chip and a corner portion of the frame-shaped dam facing the corner portion of the semiconductor chip.

As described above, as the conventional techniques, there have been proposed the techniques for restricting the outflow range of the resin overflowing from the gap between the wiring board and the semiconductor chip mounted thereon onto the periphery thereof after the underfill resin is filled into the gap between the board and the chip. Note that, in any of the techniques, the board surface on which the resin flows is not flat, and the protection resist layer (solder resist layer) is provided around the chip mounting area on the board. In addition to the role of protecting the wiring pattern, the protection resist layer (solder resist layer) contributes to prevention of outflow of the resin overflowing from the gap between the chip and the board. Specifically, outflow of the underfill resin onto the periphery thereof is restricted by the cooperative action of the protection resist layer (solder resist layer) and the dam member provided thereon. Thereby, the fluidity of the resin can be roughly managed.

However, in these techniques, a wiring board in a form having a flat board surface on which underfill resin flows is not taken into consideration. Examples of such a wiring board include a semiconductor package in the form of a so-called “coreless substrate” in which a pad is exposed from an outermost resin layer (insulating layer) on the chip mounting surface side, and in which the surface of the resin layer is flat.

### SUMMARY OF THE INVENTION

An object of the present invention is to provide a wiring board which has a flat board surface where underfill resin flows, and which restricts an outflow range of the resin and allows fluidity of the resin to be roughly managed, and a method of manufacturing the same.

According to one aspect of the invention, there is provided a method of manufacturing a wiring board, including: forming a first resist layer on a support base member, the first resist layer being patterned to have an annular opening portion surrounding a portion corresponding to an electronic component mounting area; forming a sacrifice conductive layer on the support base member exposed from the opening portion of the first resist layer; forming a second resist layer on the support base member and the sacrifice conductive layer after removing the first resist layer, the second resist layer being patterned to have an opening portion in a required shape at the portion corresponding to the electronic component mounting area; forming a pad on the support base member exposed from the opening portion of the second resist layer; forming an insulating layer on the support base member and the sacrifice conductive layer, with the pad being exposed from the insulating layer, after removing the second resist layer; forming on the insulating layer, a wiring layer including a via connected to the pad; and alternately stacking a required number of insulating layers and wiring layers and then removing the support base member and the sacrifice conductive layer.

With the method of manufacturing a wiring board according to this aspect, there is manufactured a wiring board having a structure in which pads are exposed from the outermost insulating layer on a surface side where an electronic component is mounted. In addition, the wiring board includes a configuration in which a recessed portion is formed in an annular shape surrounding an area (electronic component mounting area) in which the pads are formed on the insulating layer, and the recessed portion is also formed with a depth equivalent to the thickness of the sacrifice conductive layer. In the structure of the wiring board, the surface of the outermost insulating layer is flat except for the area of the recessed portion.

The recessed portion formed in an annular shape around the electronic component mounting area functions as a “dam” which holds back resin outflowing from a gap to the periphery thereof, when an electronic component such as a chip is mounted on the wiring board, and underfill resin is filled into the gap formed therebetween. Specifically, since the outflow of the resin onto the periphery is restricted in the recessed portion, fluidity of the resin on the board surface can be roughly managed by properly selecting the depth of the recessed portion.

According to another aspect of the invention, there is provided a method of manufacturing a wiring board, including: forming a first resist layer on a support base member, the first resist layer being patterned to have only an annular portion surrounding an electronic component mounting area; forming a sacrifice conductive layer on the support base member exposed from the first resist layer; forming a second resist layer on the support base member and the sacrifice conductive layer after removing the first resist layer, the second resist layer being patterned to have an opening portion in a required shape at a portion corresponding to the electronic component mounting area; forming a pad on the sacrifice conductive layer exposed from the opening portion of the second resist layer; forming an insulating layer on the support base member and the sacrifice conductive layer, with the pad being exposed from the insulating layer, after removing the second resist layer; forming on the insulating layer, a wiring layer including a via connected to the pad; and alternately stacking a required number of insulating layers and wiring layers and then removing the support base member and the sacrifice conductive layer.

With this method of manufacturing a wiring board, according to this aspect, there is manufactured a wiring board having a structure in which pads are exposed from the outermost insulating layer on a surface side where an electronic component is mounted. In addition, the wiring board includes a configuration in which a projected portion is formed in an annular shape surrounding an area (electronic component mounting area) in which the pads are formed on the insulating layer, and the projected portion is formed with a height equivalent to the thickness of the sacrifice conductive layer. In the structure of the wiring board as well, the surface of the outermost insulating layer is flat except for the area of the projected portion. The projected portion functions as a “dam” which restricts the underfill resin from outflowing onto the periphery thereof, as in the case of the aforementioned aspect, the underfill resin used to fill the gap at the time of mounting the electronic component. Thereby, fluidity of the resin on the board surface can be roughly managed.

Moreover, according to another aspect of the present invention, there is provided a wiring board fabricated by a method of manufacturing a wiring board according to each of the aforementioned aspects.

With reference to the following embodiments of the invention, descriptions are given below of other features in configuration of the wiring board and the method of manufacturing the same according to the present invention, and characteristic advantages based on the features thereof, and so on.

### BRIEF DESCRIPTION OF THE DRAWINGS

FIGS. 1A and 1B are diagrams showing a configuration of a wiring board (semiconductor package) according to a first embodiment of the present invention;

FIG. 2 is a cross-sectional view showing a configuration example (semiconductor device) in the case where a semiconductor element (electronic component) is mounted on the wiring board shown in FIGS. 1A and 1B;

FIGS. 3A to 3E are cross-sectional views showing steps of a method of manufacturing the wiring board shown in FIGS. 1A and 1B;

FIGS. 4A to 4D are cross-sectional views showing manufacturing steps subsequent to the steps in FIGS. 3A to 3E;

FIGS. 5A to 5C are cross-sectional views showing manufacturing steps subsequent to the steps in FIGS. 4A to 4D;

FIGS. 6A and 6B are diagrams showing a configuration of a wiring board (semiconductor package) according to a second embodiment of the present invention;

FIG. 7 is a cross-sectional view showing a configuration example (semiconductor device) in the case where a semiconductor element (electric component) is mounted on the wiring board shown in FIGS. 6A and 6B;

FIGS. 8A to 8E are cross-sectional views showing steps of a method of manufacturing the wiring board shown in FIGS. 6A and 6B;

FIGS. 9A to 9D are cross-sectional views showing manufacturing steps subsequent to the steps in FIGS. 8A to 8E;

FIGS. 10A to 10C are cross-sectional views showing manufacturing steps subsequent to the steps in FIGS. 9A to 9D;

FIGS. 11A and 11B are diagrams showing a configuration of a wiring board (semiconductor package) according to a modification example of the first embodiment; and

FIGS. 12A and 12B are cross-sectional views showing a configuration of a wiring board (semiconductor package) according to another embodiment of the case where a chip mounting surface and an external connection terminal bonding surface are set upside down and then used.

### DESCRIPTION OF THE PREFERRED EMBODIMENTS

Hereinafter, descriptions are given below of preferred embodiments of the present invention with reference to the accompanying drawings.

### First Embodiment

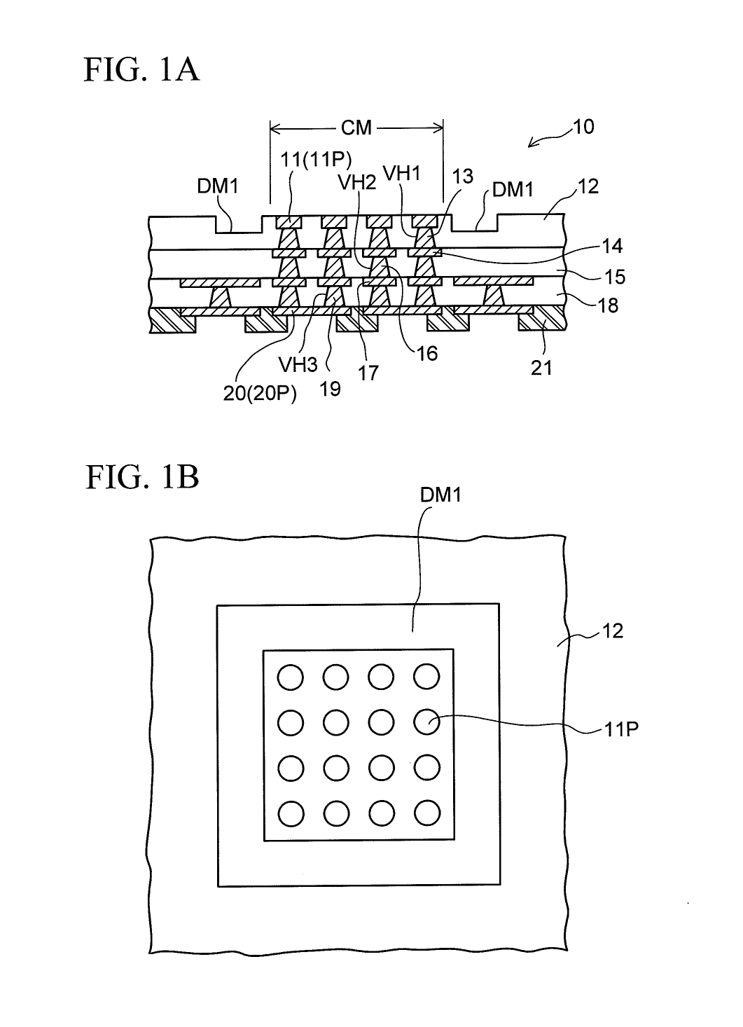

### See FIGS. 1a to 5c

FIGS. 1A and 1B show a configuration of a wiring board (semiconductor package) according to a first embodiment of the present invention. FIG. 1A shows the configuration of the wiring board when viewed in cross section. FIG. 1B schematically shows the configuration of the wiring board when viewed from above.

As illustrated, a wiring board (semiconductor package) 10 according to this embodiment has a structure in which multiple wiring layers 11, 14, 17 and 20 are stacked one on top of another with insulating layers (specifically, resin layers) 12, 15 and 18 interposed therebetween. In this structure, the wiring layers 11, 14, 17 and 20 are interlayer connected via conductors (vias 13, 16 and 19) filled into via holes VH1, VH2 and VH3 formed on the insulating layers 12, 15 and 18, respectively. Specifically, the wiring board 10 has the form of a “coreless substrate,” which does not include a support base member, and is different from a wiring board fabricated by using a general build-up process (in which a required number of build up layers are sequentially stacked on both surfaces or a single surface of a core substrate serving as a support base member).

On one of surfaces (bottom side in the illustrated example) of the coreless substrate, a solder resist layer (insulating layer) 21 functioning as a protection film is formed so as to cover the surface except for pads 20P each defined at a required position of the outermost wiring layer (wiring layer 20 in the illustrated example). In addition, pads 11P (each being a portion defined at a required position of the wiring layer 11) are exposed from a surface on the side (upper side in the illustrated example) opposite to the side on which the solder resist layer 21 is formed. These pads 11P are formed so that the upper surfaces thereof can be flush with the upper surface of the resin layer (insulating layer 12).

In the present embodiment, to the pads 11P exposed from the insulating layer 12 on an upper side, electrode terminals of a semiconductor element (chip) or the like to be mounted on the package 10 are flip-chip bonded via solder bumps or the like, respectively. To the pads 20P exposed from the solder resist layer 21 on a bottom side, external connection terminals such as solder balls for use in mounting of the package 10 on a motherboard or the like are bonded, respectively. Specifically, the surface on the upper side is a “chip mounting surface,” and the surface on the bottom side is an “external connection terminal bonding surface.”

However, depending on conditions, environments, or the like where the package 10 is used, the package 10 can be used in a form in which the chip mounting surface and the external connection terminal bonding surface are upside down. In this case, external connection terminals are bonded to the pads 11P on the upper side, and electrode terminals of a semiconductor element or the like are bonded to the pads 20 on the bottom side.

Note that, the solder resist layer 21 formed on one of the surfaces of the wiring board 10 fulfills a function as a reinforcing layer in addition to the function as a protection film. Specifically, the wiring board 10 is a coreless substrate having a low rigidity, and the thickness thereof is also thin, so that it is undeniable that the strength of the board decreases more than a little. However, the solder resist layer 21 is formed on one of the surfaces of the board as illustrated in order to reinforce the board.

Moreover, a recessed portion DM1 characterizing the present invention is formed on the resin layer 12, which is the outermost layer on the chip mounting surface side. As illustrated, the recessed portion DM1 is formed with a predetermined depth and in an annular shape surrounding an area (chip mounting area CM) in which the pads 11P are arranged on the resin layer 12 (refer to FIG. 1B). Specifically, formation of the recessed portion DM1 in an annular shape around the chip mounting area CM enables the recessed portion DM1 to function as a “dam” for blocking resin overflowing from a gap between a chip and the package 10 onto the periphery thereof, when the chip is mounted on the package 10, and the underfill resin is filled into the gap.

The specific material, size, thickness and the like of each of the members forming the wiring board (semiconductor package) 10 according to this embodiment are specifically described in relation to processing to be described later.

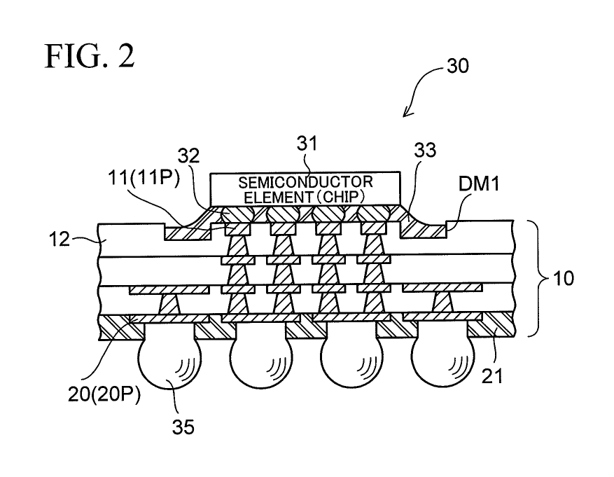

On the wiring board (semiconductor package) 10 of this embodiment, electrode terminals of a semiconductor element (chip) or the like are bonded to the pads 11P exposed from one of the surfaces of the wiring board 10, and external connection terminals such as solder balls are bonded to the pads 20P exposed from the other surface thereof, as described above. FIG. 2 is a diagram showing a configuration example of the wiring board 10.

The example shown in FIG. 2 shows a state in which a semiconductor element (chip) 31 as an electronic component is mounted on the wiring board 10. Specifically, FIG. 2 shows a cross-sectional structure in a case where a semiconductor device 30 is formed. The semiconductor chip 31 is flip-chip bonded to the pads 11P via electrode terminals 32 (solder bumps or the like) thereof as illustrated. Moreover, underfill resin 33 (thermosetting epoxy resin or the like) is filled into a gap between the wiring board 10 and the chip 31 mounted thereon. Then, the underfill resin 33 is thermally cured, thereby, increasing the connection reliability between the chip 31 and the wiring board 10.

As shown in FIG. 2, the resin outflowing from the gap between the chip 31 and the wiring board 10 onto the periphery thereof is blocked at the recessed portion DM1. Specifically, “outflowing” of the underfill resin 33 overflowed from the gap between the chip and the board onto the periphery thereof after the resin is filled is blocked within a predetermined range. Thereby, a wiring, a circuit element and the like arranged around the chip are prevented from being negatively influenced by the outflow of the resin.

Meanwhile, solder balls 35 are bonded by reflow soldering to the pads 20P on the surface (external connection terminal bonding surface) opposite to the chip mounting surface. In the illustrated example, the form of a BGA (ball grid array) in which the solder balls 35 are bonded to the pads 20P, respectively, are employed. However, it is possible to employ the form of a PGA (pin grid array) in which pins are bonded to the pads, respectively, or the form of an LGA (land grid array) in which the pads themselves are made to be external connection terminals, as well. In addition, it is also possible to employ a configuration in which the arrangement form of the wiring board 10 is reversed (upside down) from that in the illustrated case. Then, the chip 31 is mounted on the surface where the pads 20P are formed, and the solder balls 35 are bonded to the pads 11P on the surface opposite to the aforementioned surface.

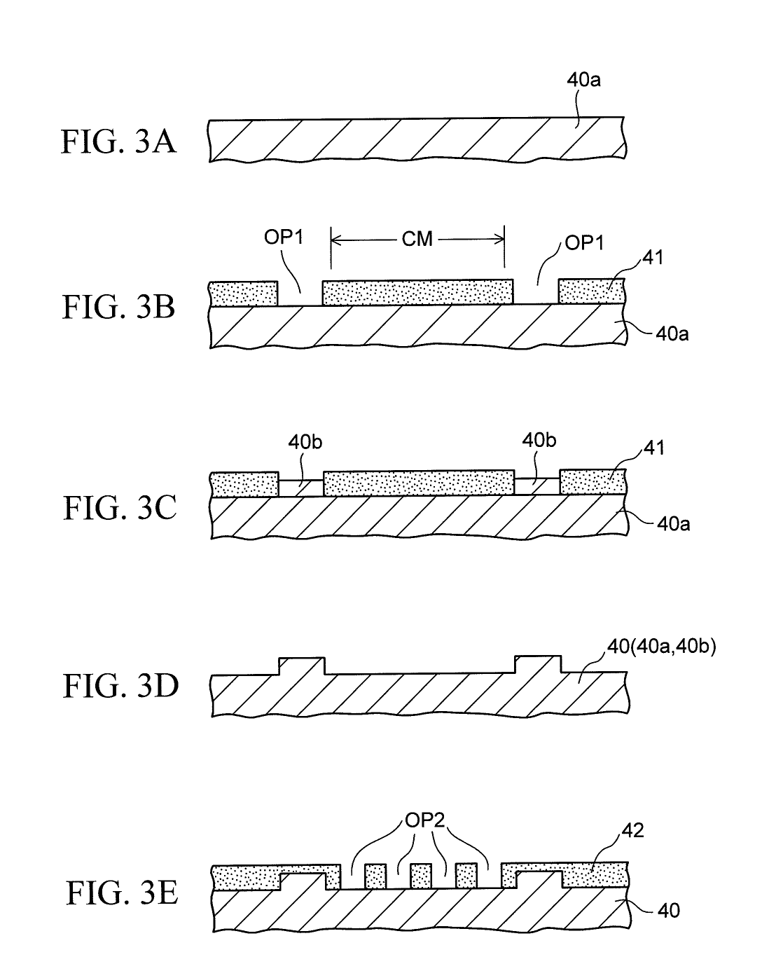

Next, a description is given of a method of manufacturing the wiring board (semiconductor package) 10 according to this embodiment with reference to FIGS. 3A to 5C showing an example of the manufacturing steps.

In the initial step (See FIG. 3A), a support base member 40a is prepared as a portion of a temporary board. As a material for the support base member 40a, a metal (typically, copper (Cu)) soluble in an etchant is used in considering that the material is eventually etched away as described later. Moreover, a metal plate or a metal foil is sufficient for use as a form of the support base member 40a, basically. Specifically, a structure (for example, the support base member disclosed in JPP (Kokai) 2007-158174)) obtained by the following manner can be preferably used as the support base member 40a. An underlying layer and a copper foil are disposed on a prepreg (e.g., a bonding sheet in a semi-cured B stage, formed by impregnating a thermosetting resin such as an epoxy-base resin or a polyimide-base resin into a glass fiber which is a reinforcement material), and then heat and pressure are applied to the prepreg to obtain the structure, for example.

In the next step (See FIG. 3B), a plating resist is formed on the support base member 40a by using a patterning material, and a required portion of the plating resist is opened (formation of a resist layer 41 provided with an opening portion OP1). The opening portion OP1 is formed by patterning in an annular shape so as to surround a portion corresponding to a chip mounting area CM, in accordance with a shape (refer to FIG. 1B) of the recessed portion DM1 eventually formed on the resin layer 12, which is the outermost layer on the chip mounting surface side.

A photosensitive dry film (a structure in which a resist material is held between a polyester cover sheet and a polyethylene separator sheet) or a liquid photoresist (liquid resist such as a novolak-base resin or an epoxy-base resin) can be used as the patterning material. For example, in a case where the dry film is used, the surface of the support base member 40a is cleaned, and thereafter, the dry film is attached thereonto by thermal compression bonding. The dry film is then cured by subjecting the dry film to exposure under ultraviolet (UV) irradiation by use of a mask (not illustrated) patterned in a required shape. Thereafter, the portion is etched away (opening portion OP1) by use of a predetermined developing solution. The resist layer 41 in accordance with the required shape of the recessed portion DM1 is thus formed. The resist layer 41 can be formed through the same steps in a case where the liquid photoresist is used as well.

In the next step (See FIG. 3C), a sacrifice conductive layer 40b is formed with a required thickness on the support base member 40a by electrolytic plating using the support base member 40a as a power feeding layer, the support base member 40a exposed through the opening portion OP1 of the resist layer 41. As the material forming the sacrifice conductive layer 40b, a metal species soluble in an etchant is selected in considering that the material is eventually etched away with the support member 40a in contact therewith. In this embodiment, since copper (Cu) is used as the material of the support base member 40a, the sacrifice conductive layer (Cu) 40b is formed on the support base member 40a by electrolytic Cu plating.

When the same material as that for the support base member 40a is selected for the sacrifice conductive layer 40b as described above, these components 40a and 40b can be simultaneously removed by one etching operation, which in turn contributes to simplification of the process.

Moreover, the required thickness of the sacrifice conductive layer 40b to be formed defines the depth of the dam (recessed portion DM1) to be formed. Accordingly, the required thickness of the sacrifice conductive layer 40b is selected in properly considering the size of the chip to be mounted, and the amount of underfill resin overflowing from the gap between the chip and the wiring board onto the periphery thereof, when the underfill resin is filled at the time of mounting the chip.

In the next step (See FIG. 3D), the plating resist (the resist layer 41 in FIG. 3C) is removed. For example, in a case where a dry film is used as the plating resist, an alkaline chemical liquid such as sodium hydroxide or a monoethanolamine-base liquid can be used for removal, for example. In addition, in a case where a liquid resist such as a novolak-base resin or an epoxy-base resin is used as the plating resist, acetone, alcohol or the like can be used for removal. Thereby, a structure 40 (also referred to as a “temporary board” for convenience) including the sacrifice conductive layer 40b formed on a predetermined position on the support base member 40a as illustrated is fabricated.

In the next step (See FIG. 3E), in the same manner as the process performed in the step in FIG. 3B, plating resist is formed by use of a patterning material on a surface side of the temporary board 40 where the sacrifice conductive layer 40b is formed, and required positions of the plating resist are opened (formation of a resist layer 42 provided with opening portions OP2). The opening portions OP2 are formed at corresponding portions in the chip mounting area CM by patterning in accordance with a required shape of the pads 11P (wiring layer 11) to be formed. A photosensitive dry film or a liquid photoresist can be used as the patterning material as in the aforementioned case.

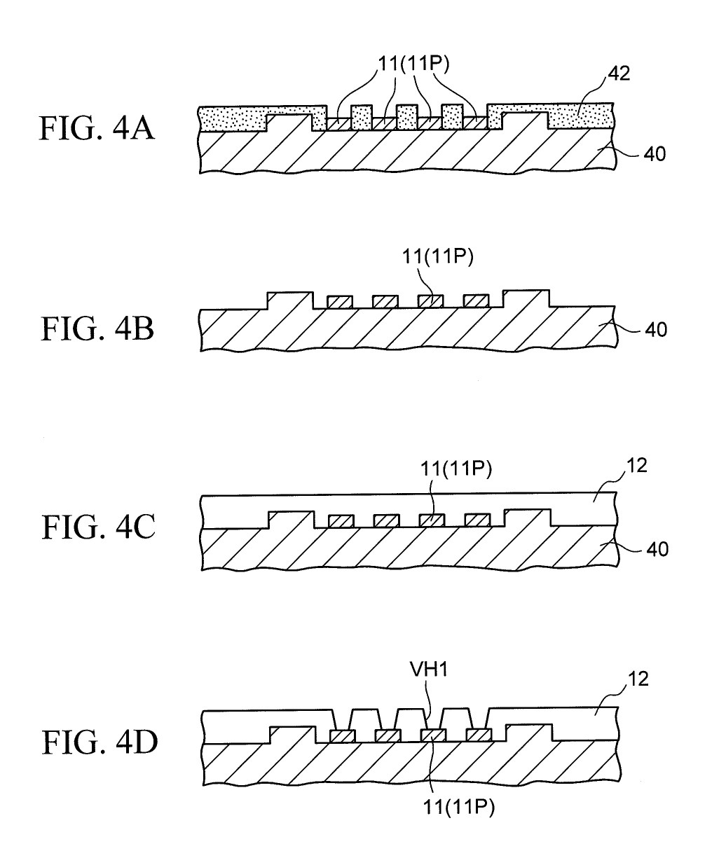

In the next step (See FIG. 4A), in the same manner as the process performed in the step in FIG. 3C, the wiring layer 11 is formed on portions of the temporary board 40 (on the support base member 40a to be specific) by electrolytic plating using the temporary board 40 as a power feeding layer, the portions of the temporary board 40 being exposed through the opening portions OP2 of the resist layer 42 (FIG. 3E). Portions (each being defined at a predetermined position) of the wiring layer 11 function as the pads 11P, respectively, for mounting a semiconductor element (or pads for bonding external connection terminals).

Each of the pads 11P to be formed is in a circular shape (refer to FIG. 1B), and the size (diameter) thereof is selected to be 50 to 150 μm. Moreover, the pad 11P is formed of a structure in which multiple metal layers are stacked. As the material forming the lowermost metal layer in this structure (the metal layer which eventually is exposed), a metal species insoluble in an etchant is selected in considering that the temporary board 40 in contact with the bottommost metal layer is eventually etched away. In this embodiment, since copper (Cu) is used as the material for the temporary board 40, gold (Au) is used as a metal different from copper in considering that good contact characteristics (soldering characteristics) can be secured.

Specifically, an Au layer having a thickness of approximately 40 nm is formed first on the temporary board (Cu) 40 by flash plating with Au, and a Pd layer having a thickness of approximately 20 nm is further formed by flash plating with palladium (Pd). Thereby, an Au/Pd layer is formed. Next, a Ni layer having a thickness of approximately 5 μm is formed on the Au/Pd layer by nickel (Ni) plating, and a Cu layer having a thickness of approximately 15 μm is further formed on the Ni layer by Cu plating. Herein, the Ni layer is formed in order to prevent the copper (Cu) contained in the metal layer, which is the upper layer thereof, from diffusing into the Au/Pd layer, which is the lower layer thereof.

To be more specific, in this step, the pads 11P each formed of a three-layer structure (strictly speaking, four-layer structure) including the Au/Pd layer, the Ni layer and the Cu layer are formed. Note that, although the Au/Pd layer is formed as the lowermost metal layer in this step, the Pd layer does not have to be necessarily formed, and this layer may be a metal layer formed of only the Au layer.

In the next step (See FIG. 4B), the plating resist (the resist layer 42 in FIG. 4A) is removed in the same manner as the process performed in the step in FIG. 3D. Thereby, a structure having the pads 11P (wiring layer 11) formed on the predetermined positions on the temporary board 40 as illustrated is fabricated.

In the next step (See FIG. 4C), the insulating layer 12 formed of an epoxy-base resin, a polyimide-base resin, or the like is formed on the surface side of the temporary board 40 where the pads 11P (wiring layer 11) are formed. For example, an epoxy-base resin film is laminated on the temporary board 40 and the pads 11P (wiring layer 11), and then, the resin film is cured by heat process at a temperature of 130 to 150° C. while the resin film is pressed. Thereby, the resin layer (insulating layer 12) can be formed.

In the next step (See FIG. 4D), opening portions (via holes VH1) which extend to the pads 11P are formed at predetermined positions (portions corresponding to the pads 11P) of the insulating layer 12, respectively, by a hole making process with a CO₂ laser, an excimer laser or the like. Note that, although a laser or the like is used to form the via holes VH1 in this step, photolithography can be also used to form required via holes VH1 when the insulating layer 12 is formed by using a photosensitive resin.

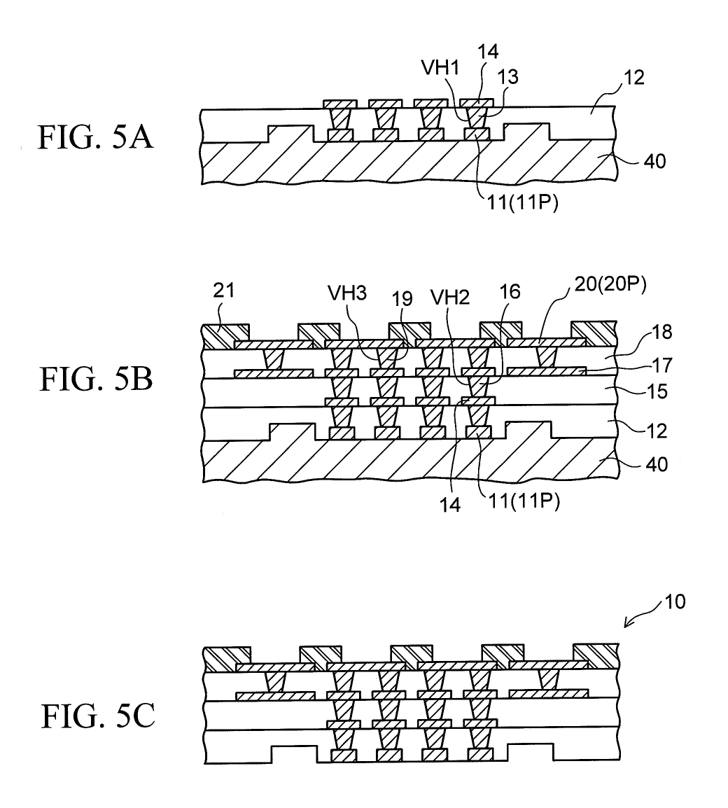

In the next step (See FIG. 5A), the wiring layer 14 having a required pattern and connected to the pads 11P is formed on the insulating layer 12 including the via holes VH1 formed therein by filling in the via holes VH1 (formation of vias 13). A semi-additive process is used for formation of the wiring layer 14, for example.

Specifically, a copper (Cu) seed layer (not illustrated) is formed on the insulating layer 12 and also in the via holes VH1 by electroless plating, sputtering or the like, first. Then, a resist film (not illustrated) is formed, the resist film including opening portions in accordance with the shape of the wiring layer 14 to be formed. Next, a conductor (Cu) pattern (not illustrated) is formed on portions of the seed layer (Cu) by electrolytic Cu plating using the seed layer as a power feeding layer, the portions of the seed (Cu) layer exposed through the opening portions of the resist film. Furthermore, the seed layer is etched by using the conductor (Cu) pattern as the mask after the resist film is removed. Thereby, the required wiring layer 14 is obtained.

Note that, other than the semi-additive process, various wiring forming methods including a subtractive process and the like can be used. In addition, the method of forming the vias 13 is not limited to electroless plating or the like, but a screen printing method can be used to form the vias 13 by filling the holes with conductive paste (silver paste, copper paste or the like).

In the next step (See FIG. 5B), the insulating layers and the wiring layers are alternately stacked in the same manner as the process performed in the steps in FIGS. 4C to 5A. In the illustrated example, two insulating layers and two wiring layers are stacked for the simplicity of description. Specifically, a resin layer (insulating layer 15) is formed on the insulating layer 12 and the wiring layer 14. Then, the via holes VH2, which extend to the pads (not illustrated) of the wiring layer 14, respectively, are formed on the insulating layer 15. Thereafter, the wiring layer 17 having a required pattern and connected to the pads is formed by filling in these via holes VH2 (formation of the vias 16). Moreover, a resin layer (insulating layer 18) is formed on the insulating layer 15 and the wiring layer 17. Then, the via holes VH3, which extend to the pads (not illustrated) of the wiring layer 17, respectively, are formed on the insulating layer 18. Thereafter, the wiring layer 20 having a required pattern and connected to the pads is formed by filling in these via holes VH3 (formation of the vias 19). The wiring layer 20 forms the outermost wiring layer in this embodiment.

Moreover, the solder resist layer 21 is formed so as to cover the surface (insulating layer 18 and wiring layer 20) excluding the pads 20P each defined at a predetermined position of the wiring layer 20. The solder resist layer 21 can be formed, for example, by laminating a solder resist film or applying a liquid solder resist onto the surface, and then patterning the resist in a required shape. In this manner, the pads 20P are exposed through the opening portions of the solder resist layer 21.

The pads 20P are preferably subjected to Au plating in order to increase contact characteristics as in the case of the pads 11P on the opposite side surface because external connection terminals such as solder balls or pins (or electrode terminals of a semiconductor chip or the like to be mounted on the wiring board 10) for use in mounting of the wiring board 10 on a motherboard or the like are bonded to the pads 20P. At this time, Ni plating is performed on the pads 20P, and thereafter, Au plating is performed. Specifically, a conductive layer having a two-layer structure (not illustrated) including the Ni layer and the Au layer is formed on the pads 20.

In the final step (See FIG. 5C), the temporary board 40 (the structure including the sacrifice conductive layer 40b formed at predetermined positions on the support base member 40a (FIG. 3D)) is selectively removed with respect to the pads 11P, the resin layer 12, the pads 20P and the solder resist layer 21. For example, by wet etching using a ferric chloride aqueous solution, a copper chloride aqueous solution, an ammonium persulfate aqueous solution or the like, the temporary board 40 formed of Cu can be selectively etched away with respect to the pads 11P (Au layer is formed on the surface layer portion thereof), the resin layer 12, the pads 20P (Au layer is formed on the surface layer portion thereof) and the solder resist layer 21.

Through the aforementioned steps, the wiring board 10 (FIG. 1) of this embodiment is fabricated.

As described above, according to the first embodiment (FIGS. 1A to 5C), there is provided the wiring board (semiconductor package) 10 having a structure in which the pads 11P are exposed from the resin layer 12, which is the outermost layer on the chip mounting surface side. The wiring board 10 also includes the recessed portion DM1 formed with a required depth and in an annular shape so as to surround the area (chip mounting area CM) where the pads 11P are disposed. In the structure of the package 10, the surface of the resin layer 12, which is the outermost layer, is flat except for the area where the recessed portion DM1 is formed.

The recessed portion DM1 formed in an annular shape around the chip mounting area CM functions as a “dam” which holds back the underfill resin 33 overflowing from the gap between the chip 31 and the package 10 onto the periphery thereof, when the chip 31 is mounted on the package 10, and the underfill resin is filled into the gap as described above. Specifically, since outflowing of the resin onto the periphery is restricted in the recessed portion DM1, fluidity of the resin on the board surface (resin layer 12) can be roughly managed by appropriately selecting the depth of the recessed portion DM1 (specifically, by appropriately selecting the thickness of the sacrifice conductive layer 40b formed in the step in FIG. 3C).

In the aforementioned processing (method of manufacturing the wiring board) according to the first embodiment, the description is given of the case, as an example, where plating is used to form the recessed portion DM1 characterizing the present invention. However, the method of forming the recessed portion DM1 is not limited to this case as a matter of course. Half-etching can be also used to form the recessed portion DM1, for example. Basically, the processing in this case is the same as the process performed in the processing (FIGS. 3A to 5C) according to the first embodiment except for process related to half-etching. A description of the different process is given as follows although an illustration thereof is not provided.

First, in the same manner as the process performed in the step in FIG. 3A, a support base member used as the temporary board is prepared, and an etching resist is formed on the support base member by use of a photosensitive dry film or the like. A resist layer is then formed by patterning the etching resist in a required shape. The resist layer is formed in a pattern reverse to the pattern of the resist layer 41 shown in FIG. 3B. Specifically, the resist layer is patterned to have only an annular resist portion surrounding the chip mounting area CM, in accordance with the shape of the recessed portion DM1 (FIG. 1B) eventually formed on the outermost resin layer 12.

Next, using the patterned resist layer as the mask, half-etching is performed on a portion where the support base member is exposed, and the portion is made thinner by removing the portion up to a required depth (the amount corresponding to the depth of the recessed portion DM1 to be formed). Then, after the resist layer (etching resist) is removed, the wiring board 10 shown in FIGS. 1A and 1B can be obtained through the same process as that performed in each of the steps after the aforementioned step in FIG. 3E.

As described above, the recessed portion DM1 can be formed by half-etching. In addition, as another method, a sandblasting method, a wet blasting method or the like can be used instead of half-etching.

Moreover, in the processing according to the first embodiment, the description is given of the case, as an example, where a projected portion (sacrifice conductive layer 40b) in accordance with the depth of the recessed portion DM1 is formed on the temporary board (support base member 40a) (FIGS. 3B to 3D), and thereafter, the pads 11P are formed at required portions, respectively, in the chip mounting area CM (FIGS. 3E to 4B). However, the order of the process is not limited to the one described above. The order of patterning processes (formation of the projected portion on the temporary board and formation of the pads) performed in the respective steps can be switched. Specifically, even when the projected portion in accordance with the depth of the recessed portion DM1 is formed on the temporary board after the pads 11P are formed at the required portions in the chip mounting area CM, the wiring board 10 (FIG. 1) having the same structure can be eventually obtained.

### Second Embodiment

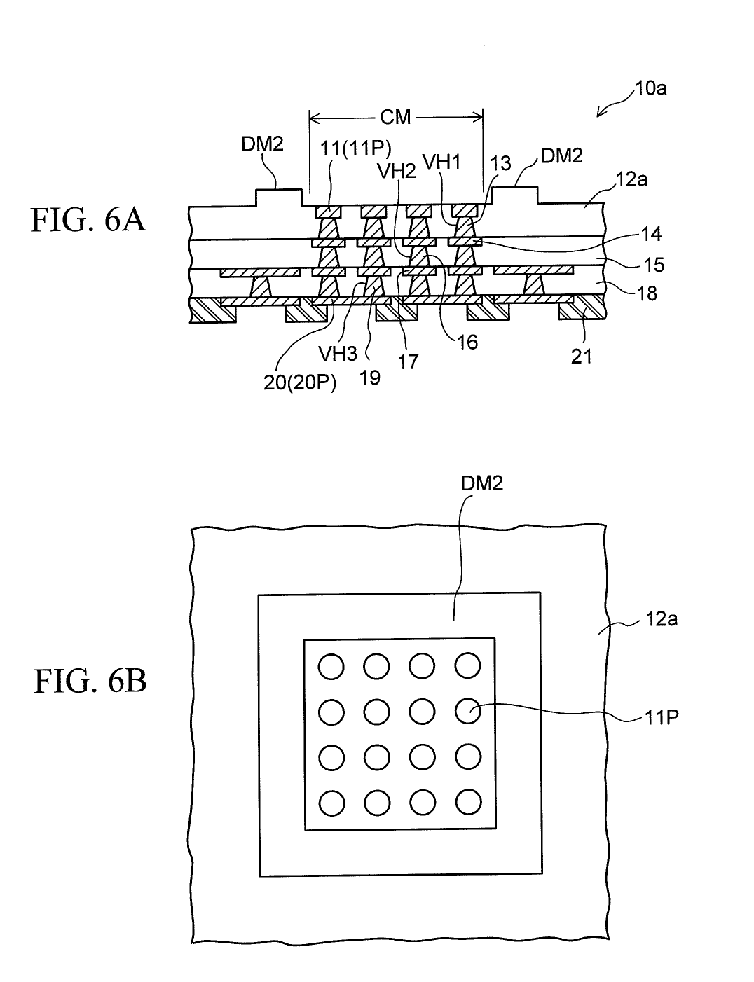

### See FIGS. 6a to 10c

FIGS. 6A and 6B show a configuration of a wiring board (semiconductor package) according to a second embodiment of the present invention. FIG. 6A shows the configuration of the wiring board when viewed in cross section. FIG. 6B schematically shows the configuration of the wiring board when viewed from above.

As compared with the configuration of the wiring board 10 (FIG. 1) according to the first embodiment, a wiring board (semiconductor package) 10a according to this embodiment is different in the following points. On a resin layer 12a, which is the outermost layer on the chip mounting surface side, a projected portion DM2 (formed of a portion of the resin) is integrally provided with the resin layer 12a. The projected portion DM2 is formed with a required height and in an annular shape so as to surround an area (chip mounting area CM) where the pads 11P are arranged on the resin layer 12a as illustrated (refer to FIG. 6B). Since the other configuration of the wiring board 10a is basically the same as that of the wiring board 10 of the first embodiment, the description thereof is omitted herein.

In this embodiment as well, formation of the projected portion DM2 in an annular shape around the chip mounting area CM enables, in the same manner, the projected portion DM2 to function as a “dam” for blocking resin outflowing from a gap between a chip and the package 10a onto the periphery thereof, when the chip is mounted on the package 10a, and the underfill resin is filled into the gap.

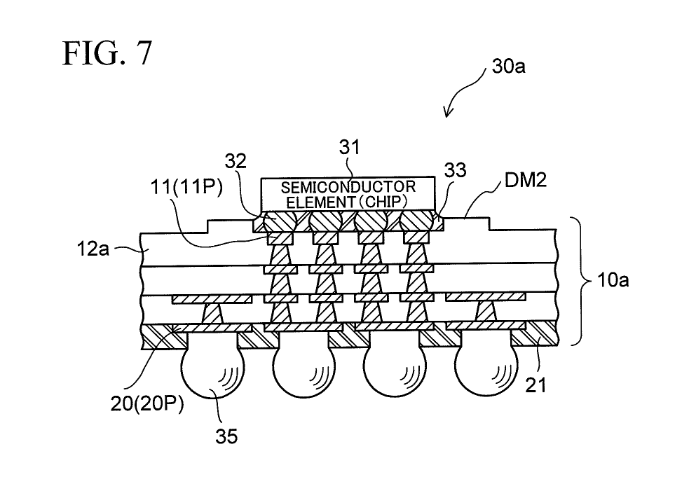

In addition, in a case of the wiring board (semiconductor package) 10a of this embodiment as well, electrode terminals of a semiconductor element (chip) or the like are bonded to the pads 11P exposed from one of the surfaces of the wiring board 10a, and external connection terminals such as solder balls are bonded to the pads 20P exposed from the other surface thereof. FIG. 7 shows a configuration example in this case.

A semiconductor device 30a (obtained by mounting a semiconductor element (chip) 31 on the wiring board 10a) illustrated in FIG. 7 basically has the same configuration as that of the semiconductor device 30 shown in FIG. 2 except that the shape of the component (projected portion DM2 in place of the aforementioned recessed portion DM1) functioning as a dam is different.

In the semiconductor device 30a as well, resin outflowing from the gap between the chip 31 and the wiring board 10a onto the periphery thereof is blocked by the dam (projected portion DM2) and is restricted from outflowing outwardly from the dam as illustrated. Thereby, a wiring, a circuit element and the like disposed around the chip are prevented from negatively influenced by the outflow of the resin.

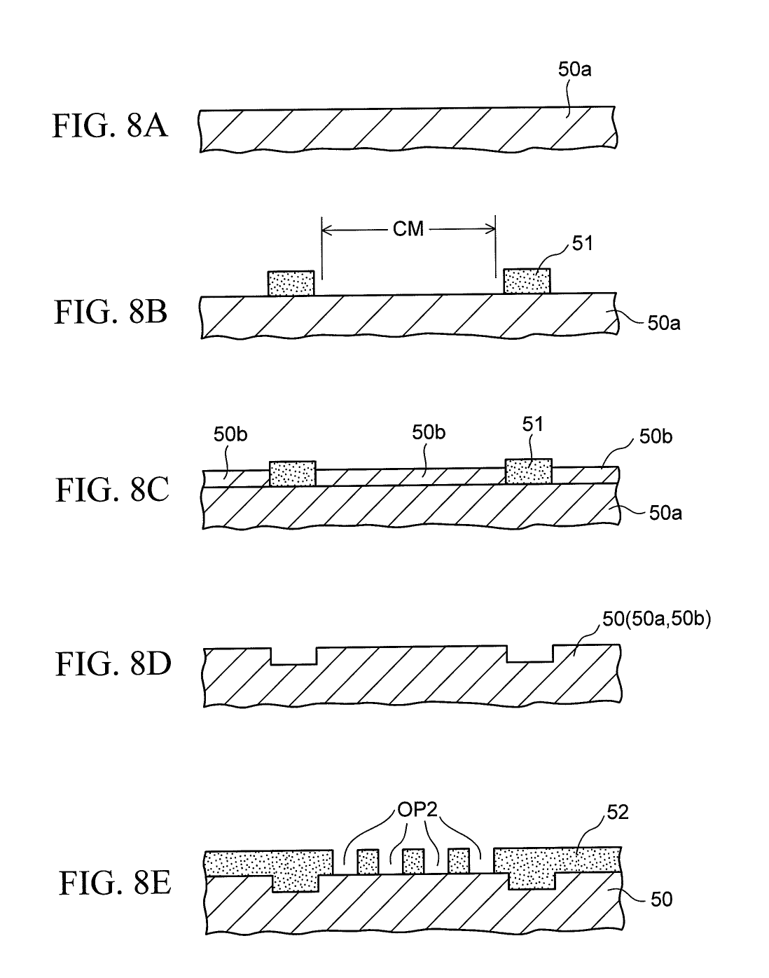

The wiring board 10a according to this embodiment can be manufactured by a method of manufacturing shown through FIGS. 8A to 10C as an example. The processing performed in each step of FIGS. 8A to 10C is basically the same as the processing performed in each step (FIGS. 3A to 5C) of the method of manufacturing according to the first embodiment. In order to avoid redundant description, the description is selectively given of only different processing.

First, a support base member 50a used as a portion of a temporary board is prepared (FIG. 8A) in the same manner as the process performed in the step in FIG. 3A. Then, a plating resist is formed on the support base member 50a by using a photosensitive dry film or a liquid photoresist, and a resist layer 51 is formed by patterning the plating resist in a required shape (FIG. 8B). The resist layer 51 is patterned to have only an annular portion surrounding the chip mounting area CM, in accordance with the shape of the projected portion DM2 (FIG. 6B) eventually formed on the resin layer 12a, which is the outermost layer on the chip mounting surface side.

In the next step (See FIG. 8C), a sacrifice conductive layer 50b is formed with a required thickness on the support base member 50a by electrolytic plating using the support base member 50a as a power feeding layer, the support base member 50a exposed from the resist layer 51. The sacrifice conductive layer (Cu) 50b is formed by performing electrolytic Cu plating on the support base member (CU) 50a in the same manner as the process performed in the step in FIG. 3C. Thus, these components 50a and 50b can be eventually removed at the same time by one etching operation.

Furthermore, the plating resist (resist layer 51) is removed (FIG. 8D). Then, in the same manner as the process performed in the step in FIG. 3E, a plating resist is formed by using a photosensitive dry film or a liquid photoresist on a surface side of the temporary board 50 where the sacrifice conductive layer 50b is formed. Thereby, a resist layer 52 provided with opening portions OP2 at required positions is formed (FIG. 8E). These opening portions OP2 are formed at corresponding portions in the chip mounting area CM by patterning in accordance with the required shape of the pads 11P to be formed.

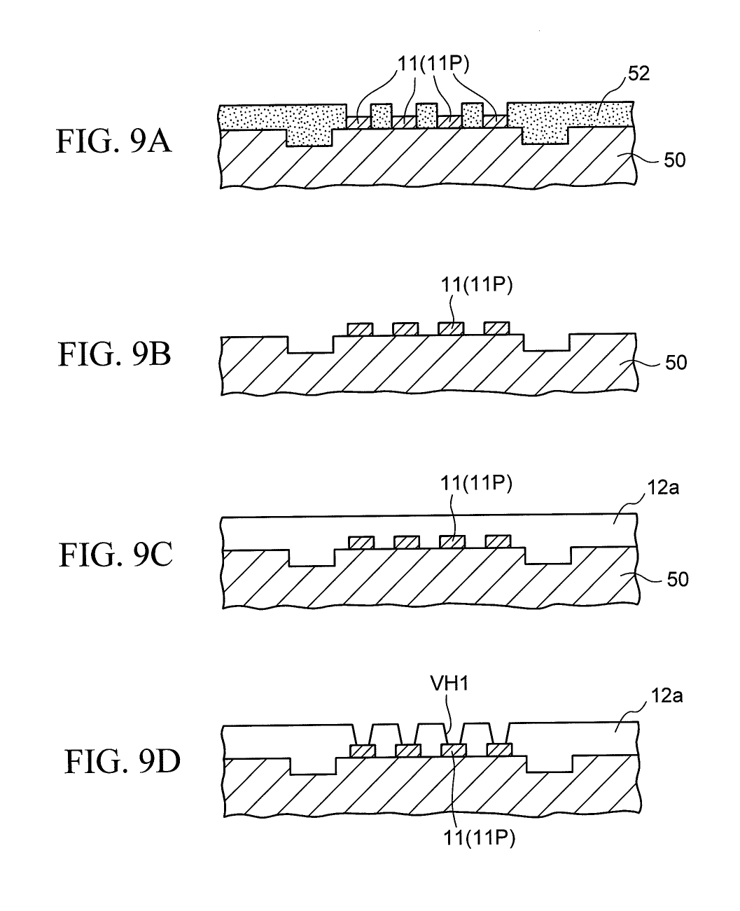

In the next step (See FIG. 9A), in the same manner as the process performed in the step in FIG. 4A, the pads 11P are formed on portions of the temporary board (on the sacrifice conductive layer 50b, to be specific) by sequentially stacking an Au/Pd layer (or Au layer), a Ni layer and a Cu layer by electrolytic plating using the temporary board 50 as a power feeding layer, the portions of the temporary board 50 exposed through the opening portions OP2 (FIG. 8E) of the resist layer 52. The size (diameter) of each of the pads 11P is the same as that in the first embodiment.

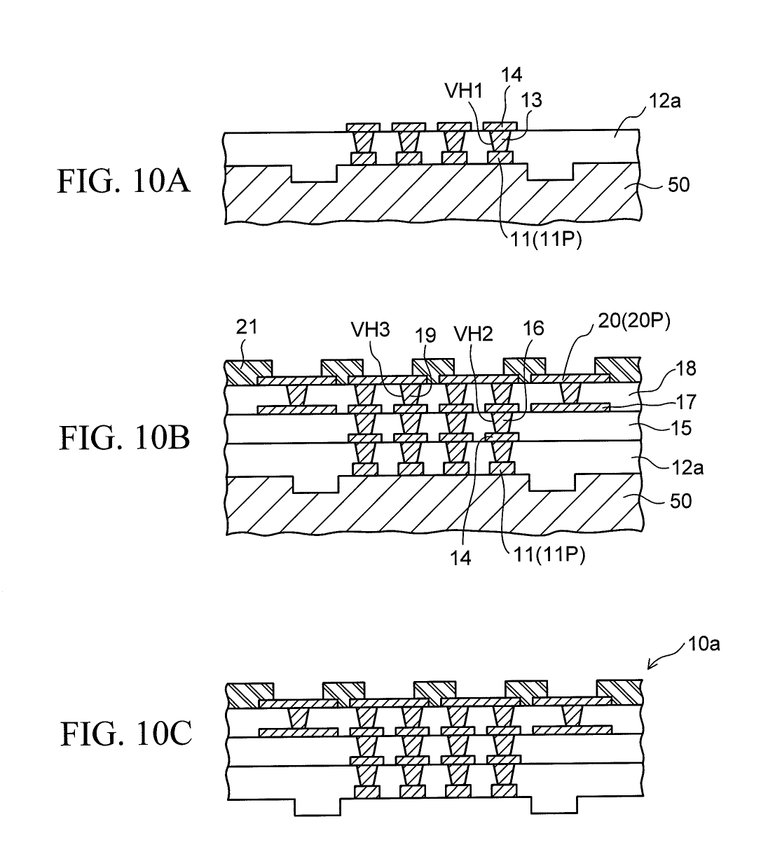

Furthermore, after the plating resist (resist layer 52) is removed (FIG. 9B), the same process as the aforementioned process performed in each step in FIGS. 4C to 5B is performed in each step in FIGS. 9C to 10B.

In the final step (See FIG. 10C), by use of the same technique as the process performed in the step in FIG. 5C, the temporary board 50 (structure in which the sacrifice conductive layer 50b is formed at a predetermined position on the support base member 50a (FIG. 8D)) is selectively etched away with respect to the pads 11P (Au layer is formed on the surface layer portion thereof), the resin layer 12a, the pads 20P (Au layer is formed on the surface layer portion thereof) and the solder resist layer 21.

Through the aforementioned steps, the wiring board 10a (FIG. 6) of this embodiment is fabricated.

Although the shape of the component (projected portion DM2) functioning as a dam is different from that of the aforementioned recessed portion DM1 as compared with the aforementioned case of the first embodiment (FIGS. 1A to 5C), the basic configuration and processing in the second embodiment (FIGS. 6A to 10C) are the same as those in the case of the first embodiment. Thus, the same operational effects as those in the first embodiment can be brought about in the second embodiment as well.

In addition, the projected portion DM2 characterizing the present invention is formed by plating in the second embodiment as well. However, half-etching can be used to form the projected portion DM2 instead of this plating method. The processing in this case is easily inferable from the contents of the description given in relation with the aforementioned half-etching in the first embodiment. Thus, the description thereof is omitted herein. Moreover, a sandblasting method, a wet blasting method or the like can be used instead of this half-etching.

### Other Embodiments

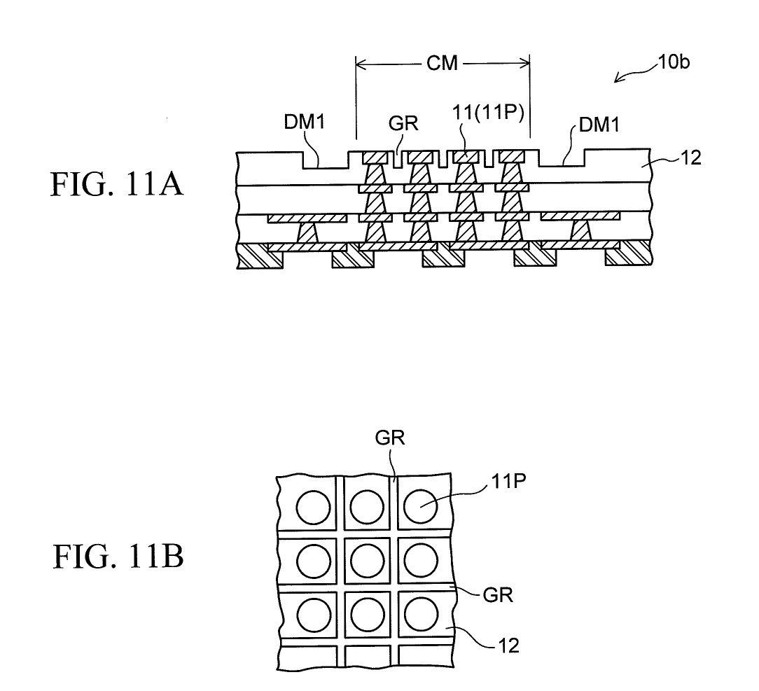

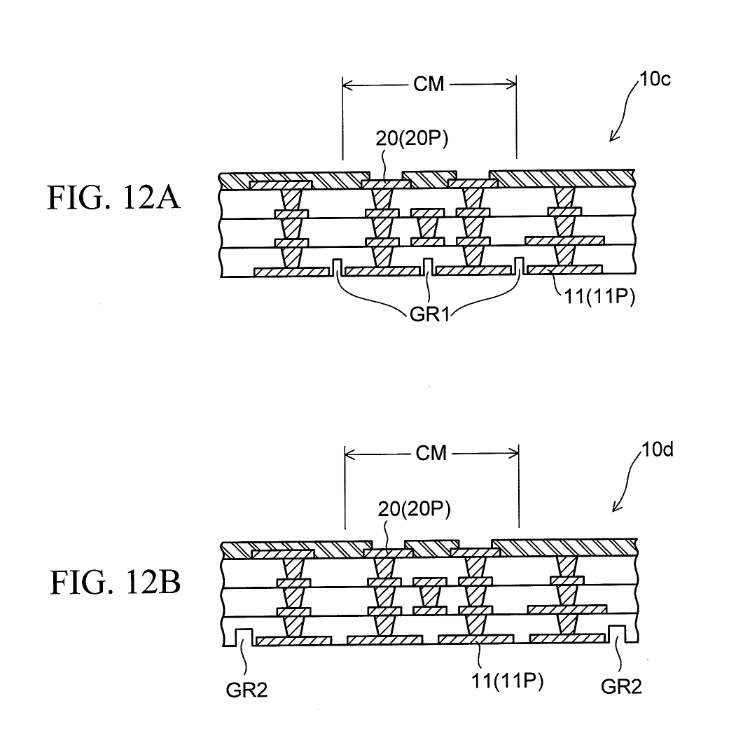

### See FIGS. 11a to 12b

FIGS. 11A and 11B show a configuration of a wiring board (semiconductor package) according to a modification example of the first embodiment. FIG. 11A shows the configuration of the wiring board when viewed in cross section. FIG. 11B schematically shows the configuration of the primary portion when the wiring board is viewed from above.

In the configuration of a wiring board (semiconductor package) 10b according to the present embodiment, the wiring board 10 (FIGS. 1A and 1B) of the first embodiment is used as the base, and a recessed portion (groove GR) is formed in a grid shape in the form of separating the pads 11P as shown in FIG. 11B in the area (chip mounting area CM) where the pads 11P are arranged on the resin layer 12, which is the outermost layer on the chip mounting surface side. The groove GR formed in the grid shape is provided for controlling (preventing) warpage of the wiring board 10b.

Specifically, the wiring board 10b is in the form of a “coreless substrate,” which does not include a support base member as in the cases of the wiring boards 10 and 10a according to aforementioned respective embodiments. Accordingly, the wiring board 10b has a low rigidity, and the thickness thereof is also thin. Thus, warpage of the wiring board 10b is assumed to occur. In particular, the possibility that warpage of the wiring board 10b occurs is high when the wiring board 10b is subjected to the heat history including heat process such as reflow soldering performed in flip chip bonding the semiconductor (element) chip, and thermosetting of the underfill resin used in filling the gap after the chip is mounted on the wiring board. This is because of the difference between the thermal expansion coefficients of the wiring layers and the resin layers and also the difference between the thermal expansion coefficients of the underfill resin and the chip material in this case.

When the groove GR in a grid shape is previously formed on the resin layer 12 on the chip mounting surface side under the assumption of the aforementioned situation, the warpage of the wiring board 10b, which may occur due to the difference between the thermal expansion coefficients, can be effectively absorbed by the portion of the groove GR. Considering the function (effect) of the groove GR described above, the groove GR does not have to be necessarily formed on the chip mounting surface side, and may be formed on the external connection terminal bonding surface side, which is opposite to the chip mounting surface side.

However, in terms of the processing, the groove GR is preferably formed on the chip mounting surface side as illustrated. Specifically, this is because the groove GR can be formed simultaneously with the recessed portion DM1 to be formed on the resin layer 12 of the same chip mounting surface side. Specifically, in the aforementioned step in FIG. 3B, when patterning of the plating resist (resist layer 41) formed on the support base member 40a is performed, patterning of an opening portion in accordance with the groove GR in a grid shape is performed with patterning of the opening portion OP1 in accordance with the shape of the recessed portion DM1. The other steps are basically the same as the aforementioned steps (FIGS. 3A to 5C) of the method of manufacturing according to the first embodiment.

Note that, although the groove GR is formed on the wiring board 10 of the first embodiment as the base in the embodiment shown in FIGS. 11A and 11B, the groove GR can be formed in the same manner for the wiring board 10a (the package including the projected portion DM2 formed around the chip mounting area CM) of the second embodiment shown in FIGS. 6A and B.

FIGS. 12A and 12B each show a configuration (cross-sectional view) of a wiring board (semiconductor package) according to another embodiment of a case where a chip mounting surface and an external connection terminal bonding surface are set upside down and then used.

In the configuration of a wiring board (semiconductor package) 10c shown in FIG. 12A, the chip mounting area CM (pads 20P are arranged in this area) is defined at a surface side where the solder resist layer is formed, and external connection terminals are bonded to the pads 11P on a surface side opposite to the aforementioned surface side, which is different from the use form of the aforementioned wiring boards 10 (10a and 10b) according to the respective embodiments. Then, a recessed portion (groove GR1) is formed in the area where the pads 11P are arranged on the resin layer on the external connection terminal bonding surface side as illustrated. The groove GR1 is formed in a grid shape in the form of separating the pads 11P and provided for (controlling) preventing warpage of the wiring board 10c, as in the case of the groove GR shown in FIG. 11B.

On the other hand, in the configuration of a wiring board (semiconductor package) 10d shown in FIG. 12B, the chip mounting area CM is defined at the surface side where the solder resist layer is formed, likewise, and external connection terminals are bonded to the pads 11P on a surface side opposite to the aforementioned surface side. However, in this embodiment, a recessed portion (groove GR2) is formed around the area where the pads 11P are arranged on the resin layer on the external connection terminal bonding surface side. The groove GR2 is also provided for controlling (preventing) warpage of the wiring board 10d as in the aforementioned case.

Note that, for the processing according to each of the aforementioned embodiments, the description is given of the case where the same metal material (Cu) is used as the material forming the support base members 40a and 50a and the sacrifice conductive layers 40b and 50b, which are etched in the last stage the processing. However, as a matter of course, the support base member and the sacrifice conductive layer do not have to be necessarily formed of the same material. Basically, it is sufficient as long as each of the components is formed of a material which can be “selectively” etched away with respect to the other exposed components when each of the support base member and the sacrifice conductive layer is etched away. In this case, since the support base member and the sacrifice conductive layer are formed of mutually different materials, the etching process is performed in two stages.

In addition, in each of the aforementioned embodiments, the description is given of the case, as an example, where a “coreless substrate,” which does not include a support base member, is used as the form of the wiring boards 10 (10a to 10d). However, as it is obvious from the gist of the present invention, the present invention is not limited to a coreless board. Basically, the present invention can be applied in the same manner to a wiring board having a core substrate fabricated by using a general build-up process, as long as the wiring board includes a pad exposed from the outermost resin layer (insulating layer) on the chip mounting surface side, and the surface (specifically, the surface where underfill resin flows) of the resin layer is flat.

What is claimed is:

1. A method of manufacturing a wiring board, comprising:
forming a first resist layer on a support base member, the first resist layer being patterned to have an annular opening portion surrounding a portion corresponding to an electronic component mounting area;
forming a sacrifice conductive layer on the support base member exposed from the opening portion of the first resist layer;
removing the first resist layer to thereby leave a convex sacrifice conductive layer on a surface of the support base member, the convex sacrifice conductive layer surrounding the electronic component mounting area;
forming a second resist layer on the support base member and the convex sacrifice conductive layer, the second resist layer being patterned to have an opening portion in a required shape at the portion corresponding to the electronic component mounting area;
forming a pad on the support base member exposed from the opening portion of the second resist layer;
forming an insulating layer on the support base member and the sacrifice conductive layer, with the pad being exposed from the insulating layer, after removing the second resist layer;
forming on the insulating layer, a wiring layer including a via connected to the pad;
alternately stacking a required number of insulating layers and wiring layers; and
removing the support base member and the convex sacrifice conductive layer to thereby form a concave portion at a portion surrounding the electronic component mounting area in an outermost insulating layer.

2. The method of manufacturing a wiring board, according to claim 1, wherein
in the formation of the sacrifice conductive layer, the sacrifice conductive layer is formed using the same material as a material constituting the support base member, and
in the formation of the pad, when the pad is formed by sequentially stacking a plurality of metal layers on the support base member by a plating method, the lowermost metal layer is formed using a material different from the material constituting the support base member and the sacrifice conductive layer.

3. A method of manufacturing a wiring board, comprising:
forming a first resist layer on a support base member, the first resist layer being patterned to have only an annular portion surrounding an electronic component mounting area;
forming a sacrifice conductive layer on the support base member exposed from the first resist layer;
removing the first resist layer to thereby leave a concave sacrifice conductive layer on a surface of the support base member, the concave sacrifice conductive layer surrounding the electronic component mounting area;
forming a second resist layer on the support base member and the concave sacrifice conductive layer, the second resist layer being patterned to have an opening portion in a required shape at a portion corresponding to the electronic component mounting area;
forming a pad on the sacrifice conductive layer exposed from the opening portion of the second resist layer;
forming an insulating layer on the support base member and the sacrifice conductive layer, with the pad being exposed from the insulating layer, after removing the second resist layer;
forming on the insulating layer, a wiring layer including a via connected to the pad;
alternately stacking a required number of insulating layers and wiring layers; and
removing the support base member and the concave sacrifice conductive layer to thereby form a convex portion at a portion surrounding the electronic component mounting area in an outermost insulating layer.

4. The method of manufacturing a wiring board, according to claim 3, wherein
in the formation of the sacrifice conductive layer, the sacrifice conductive layer is formed using the same material as a material constituting the support base member, and
in the formation of the pad, when the pad is formed by sequentially stacking a plurality of metal layers on the sacrifice conductive layer by a plating method, the lowermost metal layer is formed using a material different from the material constituting the support base member and the sacrifice conductive layer.

5. The method of manufacturing a wiring board, according to claim 1, wherein
in the formation of the first resist layer, the first resist layer is patterned to further have an opening portion in a grid shape separating the pads in the electronic component mounting area, and
in the formation of the sacrifice conductive layer, the sacrifice conductive layer is formed on the support base member exposed from each opening portion of the first resist layer.

6. A method of manufacturing a wiring board, comprising:
forming on a support base member, a recessed portion or a projected portion in an annular shape surrounding a portion corresponding to an electronic component mounting area;
forming a resist layer on a surface of the support base member where the recessed portion or projected portion is formed, the resist layer being patterned to have an opening portion in a required shape at the portion corresponding to the electronic component mounting area;
forming a pad on the support base member exposed from the opening portion of the resist layer;
forming an insulating layer on the support base member, with the pad being exposed from the insulating layer, after removing the resist layer;
forming on the insulating layer, a wiring layer including a via connected to the pad; and
alternately stacking a required number of insulating layers and wiring layers and then removing the support base member.

7. The method of manufacturing a wiring board, according to claim 6, wherein, in the formation of the recessed portion or the projected portion on the support base member, when the projected portion is formed, a portion on the support base member except for a projected portion formation area is made thinner by etching to have a required thickness.

8. A wiring board comprising:
a structure in which a plurality of wiring layers are stacked one on top of another with an insulating layer interposed therebetween, and the plurality of wiring layers are connected to one another through a via formed in each of the insulating layers; and
a recessed portion formed on an outermost insulating layer of the structure which is on a surface side where an electronic component is mounted, the recessed portion being formed in an annular shape surrounding an electronic component mounting area.

9. A wiring board comprising:
a structure in which a plurality of wiring layers are stacked one on top of another with an insulating layer interposed therebetween, and the plurality of wiring layers are connected to one another through a via formed in each of the insulating layers; and
a projected portion formed on an outermost insulating layer of the structure which is on a surface side where an electronic component is mounted, the projected portion being formed in an annular shape surrounding an electronic component mounting area.

10. The wiring board according to claim 8, further comprising a recessed portion formed in a grid shape so as to separate between pads arranged in the electronic component mounting area of the outermost insulating layer.
